(19) United States
(12) Patent Application Publication
(10) Pub. No.: US 2009/0224227 A1
(43) Pub. Date: Sep. 10, 2009

(54) TYPE-II InAs/GaSb SUPERLATTICE PHOTODIODE AND METHOD OF OPTIMIZING QUANTUM EFFICIENCY

(76) Inventor: Manijeh Razeghi, Wilmette, IL (US)

Correspondence Address: Husch Blackwell Sanders, LLP;Husch Blackwell Sanders LLP Welsh & Katz, 120 S RIVERSIDE PLAZA, 22ND FLOOR, CHICAGO, IL, 60606, US

(21) Appl. No.: 12/043,205

(22) Filed: Mar. 6, 2008

(51) Int. Cl. H01L 31/0352; H01L 31/18; H01L 21/22

(52) U.S. Cl. 257/17; 438/94; 438/510; 257/E31.036; 257/E21.135

(57) ABSTRACT

A type-II InAs/GaSb superlattice photodiode for optimizing quantum efficiency without reducing the differential resistance area product at zero bias. The photodiode features a GaSb: Be buffer, a In/GaSb: Be superlattice, a p-type doped π region, a InAs: Si/GaSb doped region, and a InAs: Si doped contact layer. The In/GaSb: Be superlattice and InAs: Si/GaSb doped region each having a thickness about two times greater than the thickness of the GaSb: Be buffer. The photodiode in one embodiment featuring a composition of InAs and GaSb with InSb forced interfaces, the composition suitable for being grown on GaSb wafers with a molecular beam epitaxy reactor. A method of optimizing quantum efficiency in a type-II InAs/GaSb superlattice photodiode having a 100% cutoff wavelength around 12 μm is further provided herewith.

### FIELD OF THE INVENTION

The present invention relates generally to an innovation of optimizing quantum efficiency of a photodiode, and specifically to a type-II InAs/GaSb superlattice photodiode having a 100% cutoff wavelength around 12 μm for optimizing quantum efficiency without reducing the differential resistance area product at zero bias (“R₀A”). The present invention further relates to a method of optimizing quantum efficiency in a type-II InAs/GaSb superlattice photodiode having a 100% cutoff wavelength around 12 μm.

### BACKGROUND OF THE INVENTION

In the 30 years since type-II InAs/GaSb superlattices were proposed, improvements in material growth, theoretical design, and experiment have demonstrated the attractiveness of this quantum system because of its flexibility in designing interband transitions. In comparison to the current state of the art, mercury cadmium telluride (“MCT”), InAs/GaSB has shown a great deal of promise in both the long wavelength infrared (LWIR) and very long wavelength infrared regimes by being able to vary layer thickness rather than the need to control the precise molar composition to tune the band alignment.

Two common figures of merit for comparing photovoltaic detectors in different material systems are the quantum efficiency (“QE”) and R₀A. Achieving high QE and high R₀A is the ultimate goal for any device, in order to have the maximum amount of incident radiation converted into electrical signal while reducing signal noise and increasing the specific detectivity D*αQE√(R₀A). In addition, for focal plane array fabrication in the LWIR, having high R₀A is the prime concern in matching material with existing commercially available readout integrated circuits. Traditionally, improving QE or R₀A has been seen as a compromise between one another. Although QE contributes more efficiently to the increase of D*, it is usually not the subject of optimization due to the limitation of material quality or due to special needs of high R₀A.

In a p-n photodiode, the external QE is determined primarily by the absorption of the material α and the diffusion length of the electrons and holes L_{e,h} and is described by the addition of the QE from the following three contributing factors (n=nₙ+n_{DR}+nₚ):

nₙ=(1−R)(αLₕ)/(αLₕ)²−1){(αLₕ−e^{-αx}^{ₙ}sh(xₙ/Lₕ))/(ch(xₙ/Lₕ))−αLₕe^{-αx}^{ₙ}}, (1)

n_{DR}=(1−R){e^{-αx}^{ₙ}−e^{-α(x}^{ₙ}^{+x}^{_{DR}}⁾}, (2)

nₚ=(1−R)(αLₑ/((αLₑ)²−1^{e-α(x}^{ₙ}^{+x}^{_{DR}}⁾)×{(−αLₑe^{-αx}^{ₚ}−sh(xₚ/Lₑ)/ch(xₚ/Lₑ))+αLₑ} (3)

where Nₙ,_{DR},ₚ is the contribution to quantum efficiency in the n, depleted, and p regions, respectively. R is the reflectivity at the air/top-surface interface and Xₙ, X_{DR}, and Xₚ are the thickness of the n, depleted, and p regions.

This quantity will increase proportionally with the device thickness, then saturate when the device thickness is comparable to the diffusion length of the carriers. For the case of type-II In/AsGaSb photodiodes with thicknesses less than 4 μm, the quantum efficiency was shown to have linear dependence on device thickness; thus it can easily be increased by just growing a thicker structure. However, if dominated by the diffusion mechanism, the dark current of the diode would increase when the device length increases, leading to decrease of R₀A.

In order to overcome the device length dependence of the dark current, the diode is designed to operate near the band-to-band tunneling regime, where the current is given using the triangular barrier approximation,

J_{T}=((q₂EV_{b})/4π² [symbol] ²)(2m*/E_{g})^{1/2}exp(−(4(2m*)^{1/2}E^{3/2})/3q [symbol] E), (4)

where V_{b} is the bias voltage, m* is the electron effective mass, and E is the maximum electric field in the junction.

Known equations for the maximum electric field do not hold true for small band gap materials where the difference between the Fermi level and the conduction band in the n region (valence band in p region) is comparable to the energy gap. In a qualitative view however, as long as the device's thickness is greater than the depletion layer thickness, the electric field is independent of the active region width and thus the overall current has a minimal dependence on the device thickness.

Thus, there exists in the art a need for a type-II InAs/GaSb superlattice photodiode with a 100% cutoff wavelength at 12 μm for optimizing quantum efficiency without reducing R₀A. There is a further need in the art for a method of making such a superlattice photodiode capable of optimizing quantum efficiency without reducing R₀A.

### SUMMARY OF THE INVENTION

One embodiment of the present invention is directed to a type-II InAs/GaSb superlattice photodiode with a 12 μm cutoff wavelength for optimizing quantum efficiency without reducing the differential resistance area product at zero bias (“R₀A”). The photodiode features a GaSb: Be buffer, a In/GaSb: Be superlattice, a p-type doped π region, a InAs: Si/GaSb doped region, and a InAs: Si doped contact layer. The In/GaSb: Be superlattice and InAs: Si/GaSb doped region each have a thickness about two times greater than the thickness of the GaSb: Be buffer and the π region can have a thickness of about 1.0 μm to about 6.0 μm. In this embodiment, the superlattice photodiode can additionally be comprised of a composition suitable for being grown on GaSb wafers with a molecular beam epitaxy reactor. Such a composition can be comprised of about 13 ML of InAs and about 7 ML of GaSb with InSb forced interfaces.

Another embodiment of the present invention is directed to a method of optimizing the quantum efficiency of a type-II InAs/GaSb superlattice photodiode with a 12 μm cutoff wavelength without reducing the differential resistance area product at zero bias (“R₀A”). In this embodiment, the method features: providing a superlattice composition of approximately 13 ML of InAs and about 7 ML of GaSb with InSb forced interfaces; providing an approximately 250 nm thick GaSb: Be buffer; providing an approximately 500 nm thick In/GaSb: Be superlattice; and providing a p-type π region; and providing an approximately 500 nm thick InAs: Si/GaSb doped region. The method additionally features slightly doping the π region, topping the photodiode with a InAs: Si doped contact layer and growing the composition on GaSb wafers with a Gen II molecular beam epitaxy reactor.

It is to be understood that the superlattice photodiode and method according to the embodiments of the present invention improves the efficiency and effectiveness of the photodiode by maximizing the amount of incident radiation converted into an electrical signal while reducing signal noise and increasing the specific detectivity. It is to be additionally understood that, further objects, features and advantages of the present invention will be apparent from the following description and the appended claims when taken in conjunction with the accompanying figures.

### BRIEF DESCRIPTION OF THE DRAWINGS

FIG. 1a is a schematic diagram of the structure of a photodiode according to one embodiment of the present invention.

FIG. 2a graphical representation of spectral response showing responsivity of superlattice photodiodes according to embodiments of the present invention at different wavelengths.

FIG. 2b is a graphical representation of spectral response showing quantum efficiency of superlattice photodiodes according to embodiments of the present invention at different wavelengths.

FIG. 2c is a graphical representation of spectral response showing the specific detectivity of superlattice photodiodes according to embodiments of the present invention at different wavelengths.

FIG. 3 is a graphical representation showing quantum efficiency as a function of π region thickness of superlattice photodiodes according to embodiments of the present invention.

FIG. 4a is a graphical representation of current density versus voltage of superlattice photodiodes according to embodiments of the present invention at 77 K.

FIG. 4b is a graphical representation of differential resistance versus voltage of superlattice photodiodes according to embodiments of the present invention at 77 K.

FIG. 5 is a graphical representation of R₀A-product dependence versus band gap energy of grown superlattice photodiodes according to embodiments of the present invention.

### DETAILED DESCRIPTION

While the present invention is susceptible of embodiment in various forms, there is shown in the drawings a number of presently preferred embodiments that are discussed in greater detail hereafter. It should be understood that the present disclosure is to be considered as an exemplification of the present invention, and is not intended to limit the invention to the specific embodiments illustrated. It should be further understood that the title of this section of this application (“Detailed Description”) relates to a requirement of the United States Patent Office, and should not be found to limit the subject matter disclosed herein.

In this disclosure, the use of the disjunctive is intended to include the conjunctive. The use of the definite article or indefinite article is not intended to indicate cardinality. In particular, a reference to “the” object or “a” object is intended to denote also one of a possible plurality of such objects.

The active layers of the photodiode of the subject invention is made from superlattices with a type-II band alignment which in turn can be formed of binary or ternary alloy systems, as known in the art. Similar to a type-I superlattice, the allowed energy states form the ‘minibands’, due to the coupling of electrons and holes in adjacent wells. However, unlike type-I superlattices, one can adjust the bandgap of type-II superlattices from a finite value to virtually zero. These superlattices resemble a direct gap semiconductor, since the minimum of the miniband in momentum space is located at the center of the Brilloin zone. Knowing the band structure and the optical absorption process in type-II superlattices, one can use conventional photovoltaic and photoconductive structures to realize high performance type-II detectors.

Type-II photoconductive devices may be grown on GaAs substrate or on InSb, InAs, Si, InP, sapphire or other materials in the λ_{c}=12 μm to λ_{c}=32 μm range operating at 80 K. Unlike HgCdTe, these detectors show excellent energy gap uniformity over a three-inch wafer area which is important for imaging applications. A series of high performance photovoltaic type-II superlattice detectors show excellent uniformity in the very long wavelength infrared (“VLWIR”) range. The main advantage of photovoltaic detectors is their suitability for staring, two-dimensional focal plane array (“FPA”) applications, where low current bias circuitry significantly reduces the array power and heat dissipation requirements.

One embodiment of the present invention is directed to a type-II supperlatice photodiode that is grown by a molecular beam epitaxy equipped with As and Sb valved cracker sources on p-type GaSb substrates. In this technique, precursor sources can be solids which are heated above their melting points in effusion cells or gases which are connected through an injector and cracker. The sources are then evaporated in the form of beams of atoms or molecules at a controlled rate onto a crystalline substrate surface held at a suitable temperature under ultra high vacuum conditions. This process is ideal because the thickness, composition and doping level of the epilayer can be very precisely controlled.

The substrate used to form the structure of the photodiode of the present invention can be GaAs, Si, Al203, MgO, SiC, ZnO, LiGaO2, LiAlO2, Cd Te, SiC, InAs, InP, Ga, Sb, InSb, MgAl204 or GaN. Preferably, GaAs is used as the substrate. The epitaxial layer quality is sensitive to the pretreatment of the substrate and the alloy composition and therefore pretreatment of the substrates prior to epitaxial growth has been found to be beneficial. One such pretreatment procedure is as follows: Dipping in H₂SO₄ for 3 minutes with ultrasonic agitation; Rinsing in Deionized H₂O; Rinsing in hot methanol; Dipping in 3% Br in methanol at room temperature for 3 minutes (ultrasonic bath); Rinsing in hot methanol; Dipping in H₂SO₄ for 3 minutes; Rinsing in deionized H₂O, and Rinsing in hot methanol.

After this treatment, it is possible to preserve the substrate for one or two weeks without repeating this treatment prior to growth. Growth takes place by introducing, metered amounts of the group-III alkyls and the group-V hydrides into a quartz reaction tube containing a substrate placed on an rf-heated susceptor surface. The hot susceptor has a catalytic effect on the decomposition of the gaseous products; the growth rate is proportional to the flow rate of the group-III species, but is relatively independent of temperature between 700° and 1000° C. and of the partial pressure of group-V species as well. The gas molecules diffuse across the boundary layer to the substrate surface, where the metal alkyls and hydrides decompose to produce the group-III and group-V elemental species. The elemental species move on the hot surface until they find an available lattice site, where growth then occurs.

The reactor and associated gas-distribution scheme used herein are substantially as described in U.S. Pat. No. 5,384,151. The system comprises a cooled quartz reaction tube pumped by a high-capacity roughing pump (120 hr⁻¹) to a vacuum between 7 and 760 Torr. The substrate was mounted on a pyrolytically coated graphite susceptor that was heated by rf induction. The pressure inside the reactor was measured by a mechanical gauge and the temperature by an infrared pyrometer. A molecular sieve was used to impede oil back-diffusion at the input of the pump. The working pressure was adjusted by varying the flow rate of the pump by using a control gate valve. The gas panel was classical, using ¼-inch stainless steel tubes. Flow rates were controlled by mass flow control.

The reactor was purged with a hydrogen flow of 4 liters min⁻¹, and the working pressure of 10-100 Torr was established by opening the gate valve that separated the pump and the reactor. The evacuation line that was used at atmospheric pressure was automatically closed by the opening of the gate valve. The gas flow rates were measured under standard conditions, i.e., 1 atm and 20° C., even when the reactor was at subatmospheric pressure.

The gas sources used in this study for the growth of GaInAs and GaInP by molecular beam epitaxy are listed below.

| Group-III Sources | Group-V Source |
|---|---|
| In(CH₃)₃ | t-butylamine |
| In(C₂H₅)₃ | NH₃ |
| (CH₃)₂In(C₂H₅) | As (CH₃)₃ |
| (CH₃)₂In(C₂H₅) | As (C₂H₅)₃ |
| Ga(CH₃)₃ | AsH₃ |
| Ga(C₂H₃)3 | PH₃ |
| | (CH₃)₃ Sb |
| | (C₂H₅)₃SB |

An accurately metered flow of purified H₂ for TMIn and TEGa is passed through the appropriate bubbler. To ensure that the source material remains in vapor form, the saturated vapor that emerges from the bottle is immediately diluted by a flow of hydrogen. The mole fraction, and thus the partial pressure, of the source species is lower in the mixture and is prevented from condensing in the stainless steel pipe work.

Pure Arsine (AsH₃) and Phosphine (PH₃) are used as a source of As and P. The metal alkyl or hydride flow can be either injected into the reactor or into the waste line by using two-way valves. In each case, the source flow is first switched into the waste line to establish the flow rate and then switched into the reactor. The total gas flow rate is about 8 liters min⁻¹ during growth. Stable flows are achieved by the use of mass flow controllers.

Besides utilizing molecular beam epitaxy (MBE) to grow high quality III-IV materials, the subject invention may alternatively or in combination employ other forms for deposition of III-IV films. Such other forms can include for example, metallorganic chemical vapor deposition (MOCVD), MOMBE (metalorganic molecular beam epitaxy), LPE (liquid phase epitaxy and VPE (vapor phase epitaxy).

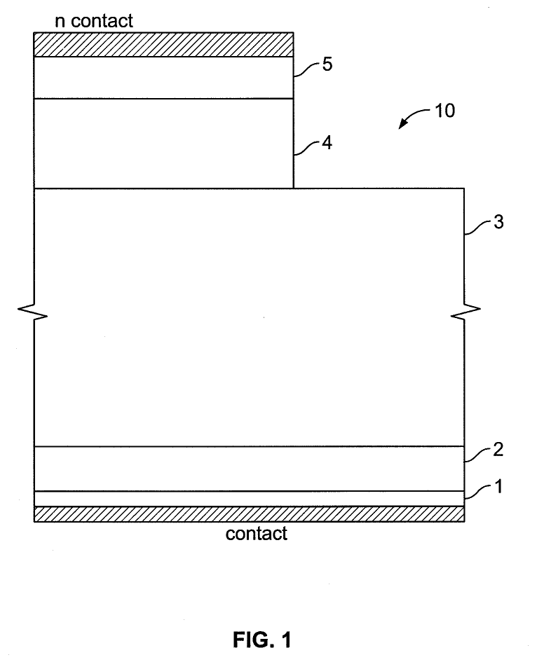

FIG. 1 is a schematic diagram of the structure of a photodiode 10, according to one embodiment of the present invention. In this embodiment, a 12 μm cutoff wavelength superlattice design having 13 ML of InAs and 7 ML of GaSb with InSb forced interfaces is provided. The superlattice is suitable for being grown on residually P-type GaSb wafers with a molecular beam epitaxy reactor. The superlattice photodiode features of a 250 nm thick GaSb:Be p⁺ buffer (p˜10¹⁸ cm−3), 1; a 500 nm thick InAs/GaSb: Be p⁺ (p˜10¹⁸ cm⁻³) superlattice, 2; a slightly p-type doped InAs: Be/GaSb region (π region), 3; a 500 nm thick InAs: Si/GaSb n+ (n˜10¹⁸ cm⁻³) region, 4; and is topped with a thin InAs: SI n+ doped (n˜10¹⁸ cm³) contact layer, 5.

The photodiode structure can be grown at 395° C. according to a calibrated pyrometer. First, a 250 nm GaSb buffer/contact layer doped with Be (p˜1×10¹⁸ cm⁻³) is deposited. Then, a 500 nm thick InAs/GaSb:Be (p˜1×10¹⁸ to 3×10¹⁷ cm⁻³) superlattice is grown followed by a slightly p-type doped InAs: Be/GaSb region (π region). Finally, a 500 nm thick InAs:Si/GaSb (n˜1×10¹⁸ cm⁻³) superlattice was grown and capped with a thin InAs:Si (n˜2×10¹⁸ cm⁻³) top contact layer. The growth rate was 0.5 monolayer/s for InAs layers and 0.8 monolayer/s for GaSb layers. The V/III beam-equivalent pressure ratio was about 4 for InAs layers and about 1.2 for GaSb layers. The cracker temperature for As and Sb cells was 800° C. The selected thickness of InAs and GaSb layers were determined for specific cutoff wavelengths using a four-band superlattice k·p model. For devices with nearly a cutoff wavelength of 12 μm, the thickness of InAs layers was about 40 Å and the thickness of the GaSb layers was 30 Å. Other type-II superlattice structures may be similarly grown utilizing the binary systems of SiGe and others. Ternary systems, as in Gaₓ In₁₋ₓ Sb/InAs and others may also be used.

In achieving the best-mode of the photodiode of the present invention, the p-doping level in the π region was increased in test structures until the current-voltage (I-V) curve of the device showed tunneling behavior and the R_{O}A versus temperature began to deviate from the diffusion-limited line (slope ˜E_{g}1kT) at 77 K. At this doping level (˜10¹⁶ cm⁻³), the tunneling mechanism became comparable with other mechanisms in the dark current, but the tunneling R₀A product at 77 K was still higher than the diffusion counterpart; the overall R₀A was not far from the diffusion-optimized case. The (˜10¹⁶ cm⁻³) doping level was then kept constant in the series of samples presented.

Doping is preferably conducted with bis-cyclopentadienyl magnesium (CP₂Mg) for p-type doping and silane (SiH₄) for n-type doping. Doping is performed through a BCP₂Mg bubbler with H2 as carrier gas and at temperatures from −15° C. to ambient temperatures at 20-1500 cm3 min.−1 and onto either a hot or cooled substrate. Dilute SiH₄ may be simply directed at ambient temperatures onto the hot, substrate at 20-90 cm3 min. 1. Dopants usable in the method of the subject invention include:

| n dopant | p dopant |
|---|---|
| H₂Se | (CH₃)₂Zn |
| H₂S | (C₂H₅)₂ Zn |
| (CH₃)₃Sn | (C₂H₅)₂ Be |
| (C₂H₅)₃Sn | (CH₃)₂Cd |
| SiH₄ | (ηC₂H₅)₂Mg |
| Si₂H₆ | Cp₂Mg |
| GeH₄ | |

In a preferred doping method for incorporating the maximum amount of p-type dopant on the layer, once the p-type layer to be doped is fully grown, the heat source is terminated and the substrate allowed to cool; the metal and hydride sources are terminated; the dopant flow, for instance DEMg, is initiated at the temperatures indicated for diffusion onto the cooled substrate/epilayer which has been previously grown. After about 2-3 minutes, the dopant flow is terminated and the next epilayer grown. By this method, it is found that 1020 atoms/cm3 of Mg may be placed on the top surface of the epilayer.

The π region thicknesses of various test-structures were varied from 1 to 6 μm. Material characterization with high resolution x-ray diffraction exhibit identical patterns for the samples and the measured superlattice periods varied from 65 to 66 Å and the deviation of lattice mismatch to GaSb substrate of all samples was less than 500 ppm. All samples were processed and characterized in exactly the same way, using standard processing techniques. The devices were not passivated, but care was taken to ensure minimal exposure to ambient atmospheric conditions. The analysis of each sample was performed on sets of diodes with device area ranging from 7.85×10⁻⁵ to 1.25×10⁻³ cm²; this ensured that diodes were not dominated by surface leakages.

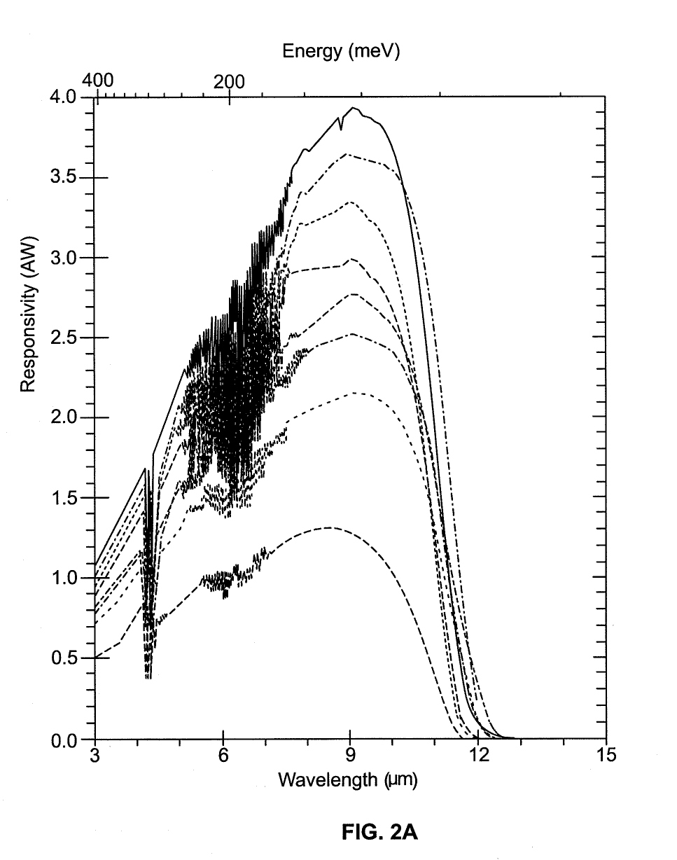

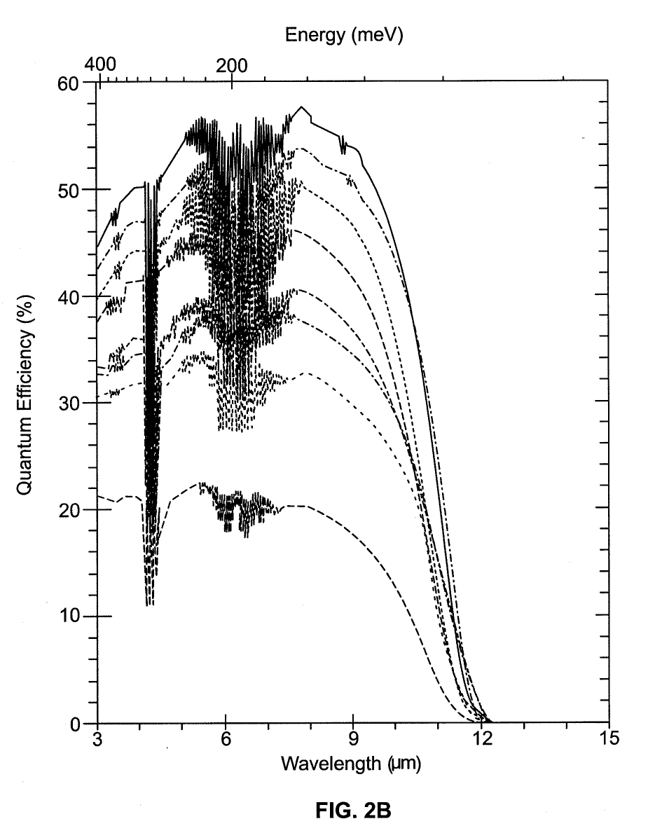

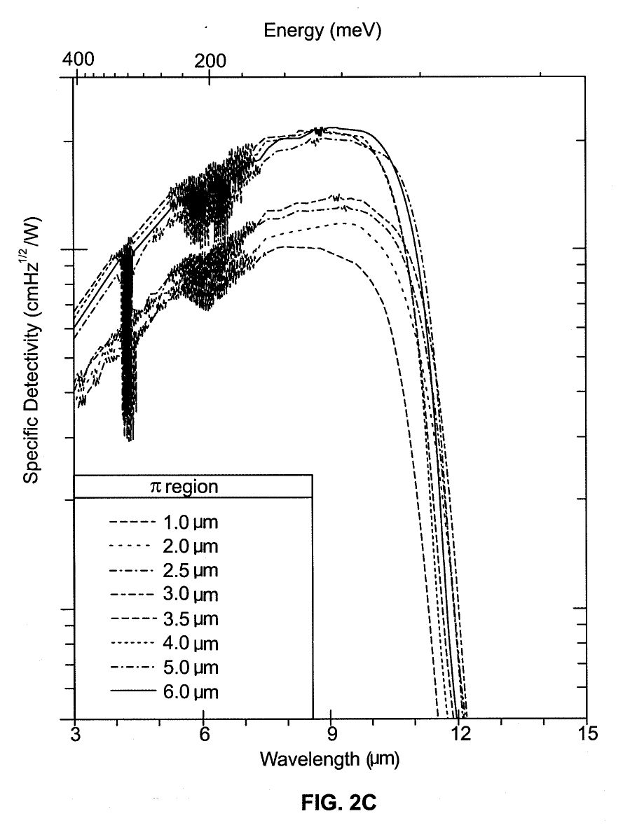

FIGS. 2a-2c show the optical characterization measured at 77 K of eight superlattice photodiodes with π region thickness ranging from 1 to 6 μm. All devices have similar 50% cutoff wavelengths at 11 μm and a 100% cutoff at 12 μm. The spectral response of the photodiodes is shown in terms of responsivity (FIG. 2a); quantum efficiency (FIG. 2b); and specific detectivity (FIG. 2c). In all three figures, the CO2 absorption at 4.2 μm is visable as well as the water vapor absorption between 5 and 8 μm. As shown in FIGS. 1a and 1b, at the peak responsivity of 9.15 μm, a single pass external QEₐᵥ of 54%±2.5% and responsivity of 3.9±0.18 A/W are obtained for photodiodes with π region thickness of 6 μm. This would give an internal QE of 78%, assuming 31% of the incident radiation is reflected at the InAs top surface. This single-pass QE, comparable to that of the state-of-the-art MCT technology, higher than any reported for the type-II superlattice system.

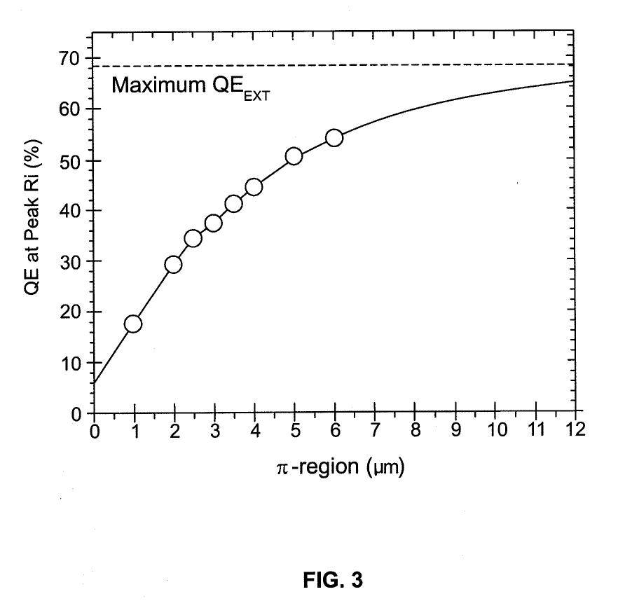

FIG. 3 is a graphical representation showing the quantum efficiency of photodiodes as a function of π-region thickness and further illustrates the extrapolation for photodiodes having thicker π-regions. When taking into account the benefit of using a semi-transparent n-type GaSb wafer, the multipass enhancement would cause the QE to reach its maximum due to complete absorption of transmitted radiation. Since the linear regime of the QE in our structures extends further than in the W-structure superlattice, this indicates that the electron diffusion length in binary/binary superlattice system is longer but it is still a limiting factor in maximizing the QE. By further improving the material quality and structural design, this length could be extended, as well the absorption coefficient could be extended, as well the adsorption coefficient could be increased; the external QE would be able to attain an even higher value.

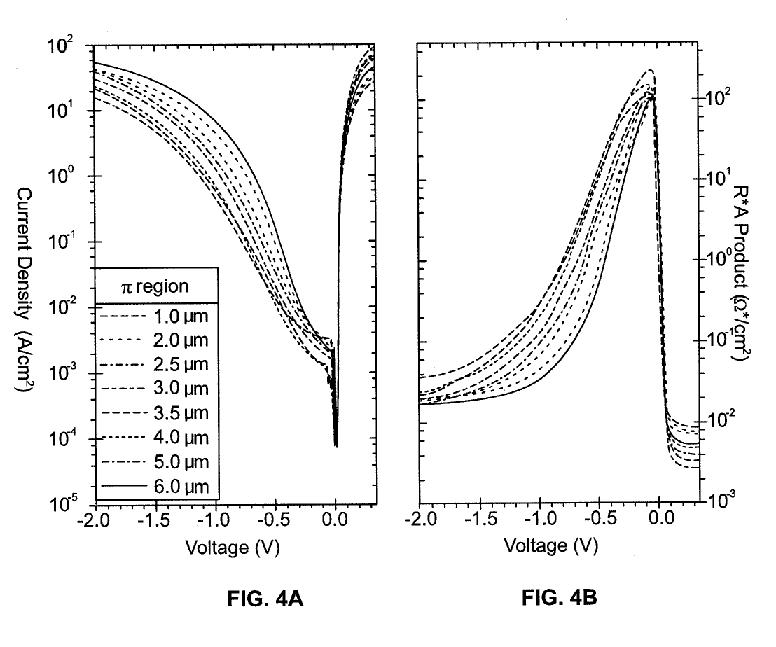

FIGS. 4a and 4b are graphical representations charting current density at various voltages (FIG. 4a) and differential resistance at particular voltages (FIG. 4b) of photodiodes at 77 K having π-region thickness between 1 to 6 μm. As shown in FIGS. 4a and 4b, The I-V and RA-V curves in FIGS. 4a and 4b exhibit typical band-to-band tunneling behavior in that the I-V curves of all samples are similar within the tolerance of the band gap variation. FIG. 4(b) clearly demonstrates a tunneling characteristic, as in the case for LWIR MCT photodiodes: the RA product reaches a maximum at small reverse bias and then exhibits a soft breakdown with increasing bias. While the product varies slightly from one sample to another, no clear relation between those values and device's thickness is observed; rather any deviation is clearly due to the variation of the cutoff wavelength. In the LWIR, a 1 μm change in wavelength is equivalent to a 10 meV difference in the band gap energy. At 77 K, this small energy difference can change the R₀A by a factor of 2.

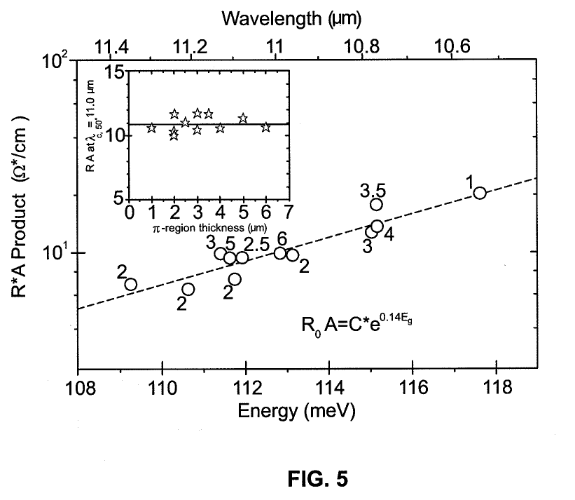

As shown in FIG. 5, the R₀A values as a function of cutoff wavelength are plotted. In FIG. 5, the numbers beside each circle indicate the photodiode's π-region thickness. Regardless of the device thickness, the R₀A values of the photodiodes are all inline with a slope of 0.14 meV−1. When normalizing the R₀A to a 50% cutoff of 11 μm, it remains flat with varying the thickness.

Evaluating the present invention to determine the best mode has demonstrated that, when operating photovoltaic diodes near the tunneling regime, the dark current is insensitive to the device thickness. This result opens a grand possibility to optimize the R₀A product and QE of photodetectors independently. The very high quantum efficiency of 54% has been obtained, proving not only the concept of independent optimization but also the excellent quality of type-II InAs/GaSb binary superlattices.

What is claimed is:

1. A type-II InAs/GaSb superlattice photodiode having a 12 μm cutoff wavelength comprising:
a GaSb: Be buffer having a particular thickness;
a In/GaSb: Be superlattice having a thickness of about two times greater than the thickness of the GaSb: Be buffer;
a p-type doped π region;
a InAs: Si/GaSb doped region having a thickness of about two times greater than the thickness of the GaSb: Be buffer;
a InAs: Si doped contact layer.

2. The superlattice photodiode of claim 1 wherein the photodiode is comprised of a composition of about 13 ML of InAs and about 7 ML of GaSb with InSb forced interfaces, the composition suitable for being grown on GaSb wafers with a molecular beam epitaxy reactor

3. The superlattice photodiode of claim 1 wherein the thickness of the GaSb: Be buffer is approximately 250 nm.

4. The superlattice photodiode of claim 1 wherein the π region has a thickness of about 1.0 μm.

5. The superlattice photodiode of claim 1 wherein the π region has a thickness of about 2.0 μm.

6. The superlattice photodiode of claim 1 wherein the π region has a thickness of about 2.5 μm.

7. The superlattice photodiode of claim 1 wherein the π region has a thickness of about 3.0 μm.

8. The superlattice photodiode of claim 1 wherein the π region has a thickness of about 3.5 μm.

9. The superlattice photodiode of claim 1 wherein the π region has a thickness of about 4.0 μm.

10. The superlattice photodiode of claim 1 wherein the π region has a thickness of about 5.0 μm.

11. The superlattice photodiode of claim 1 wherein the π region has a thickness of about 6.0 μm.

12. The superlattice photodiode of claim 2 wherein the composition is suitable for being grown on residually p-type GaSb wafers.

13. The superlattice photodiode of claim 2 wherein the composition is suitable for being grown on n-type GaSb wafers.

14. A type-II InAs/GaSb superlattice photodiode having a 12 μm cutoff wavelength comprising:
an approximately 250 nm thick GaSb: Be buffer;
an approximately 500 nm thick In/GaSb: Be superlattice;
a p-type doped π region;
an approximately 500 nm thick InAs: Si/GaSb doped region; and
a InAs: Si doped contact layer.

15. The superlattice photodiode of claim 12 wherein the photodiode is comprised of a composition of about 13 ML of InAs and about 7 ML of GaSb with InSb forced interfaces, the composition suitable for being grown on GaSb wafers with a molecular beam epitaxy reactor.

16. The superlattice photodiode of claim 12 wherein the π region has a thickness of about 1.0 μm.

17. The superlattice photodiode of claim 12 wherein the π region has a thickness of about 2.0 μm.

18. The superlattice photodiode of claim 12 wherein the π region has a thickness of about 2.5 μm.

19. The superlattice photodiode of claim 12 wherein the π region has a thickness of about 3.0 μm.

20. The superlattice photodiode of claim 12 wherein the π region has a thickness of about 3.5 μm.

21. The superlattice photodiode of claim 12 wherein the π region has a thickness of about 4.0 μm.

22. The superlattice photodiode of claim 12 wherein the π region has a thickness of about 5.0 μm.

23. The superlattice photodiode of claim 12 wherein the π region has a thickness of about 6.0 μm.

24. The superlattice photodiode of claim 12 wherein the composition is suitable for being grown on residually p-type GaSb wafers.

25. The superlattice photodiode of claim 12 wherein the composition is suitable for being grown on n-type GaSb wafers.

26. A method of optimizing quantum efficiency in a type-II InAs/GaSb superlattice photodiode having a 100% cutoff wavelength around 12 μm, comprising:
providing a superlattice composition of approximately 13 ML of InAs and about 7 ML of GaSb with InSb forced interfaces;
providing an approximately 250 nm thick GaSb: Be buffer;
providing an approximately 500 nm thick In/GaSb: Be superlattice;
providing a p-type π region between 1 and 6 μm;
doping the π region;
providing an approximately 500 nm thick InAs: Si/GaSb doped region;
topping the photodiode with a InAs: Si doped contact layer; and
growing the composition on GaSb wafers with a molecular beam epitaxy reactor.
